(19) United States
(12) Patent Application Publication
(10) Pub. No.: US 2009/0151986 A1
(43) Pub. Date: Jun. 18, 2009

(54) Method of manufacturing wiring board, wiring board, and semiconductor device

(75) Inventor: Shinji Mitsuzono, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/292,434

(22) Filed: Nov. 19, 2008

(30) Foreign Application Priority Data
Dec. 18, 2007 (JP) 2007-325816

(51) Int. Cl. H05K 1/00; H05K 3/00

(52) U.S. Cl. 174/250; 29/829

(57) ABSTRACT

A plurality of mounting terminals, a plane electrode formed around the plurality of mounting terminals, and a plurality of interconnects for plating, each of which is respectively connected to the plane electrode and a plurality of the mounting terminals different from each other are formed at one surface of the wiring board. The method of manufacturing the wiring board includes forming a mask film for plating on the insulating base, and forming a plated film on the mounting terminals and the interconnects for plating exposed out from the mask film; disposing, on the mask film for plating, a mask for removing interconnect so as to cover the plurality of openings for mounting terminals out of the regions having the plated film formed therein; and removing, through the mask for removing interconnect, the plated film and the interconnects for plating exposed out from the mask for removing interconnect.

This application is based on Japanese patent application No. 2007-325816 the content of which is incorporated hereinto by reference.

### BACKGROUND

1. Technical Field

The present invention relates to a method of manufacturing a wiring board, a wiring board, and a semiconductor device.

2. Related Art

In order to deposit Ni, Au or the like by electrolytic plating onto mounting terminal portions of a wiring board, it has been necessary to supply electric current to the mounting terminals by drawing a feeder interconnect typically composed of copper out from the target mounting terminals, and connecting the interconnect to a feeder conductor on a panel portion outside the wiring board.

Japanese Laid-Open Patent Publication No. 2001-68588 describes a technique of electrolytic plating onto the mounting terminals, by centralizing a plurality of feeder conductors, respectively connected to a plurality of mounting terminals, into a centralization region, connecting them to a common planar grounding conductor, and supplying current through the planar grounding conductor. After completion of the electrolytic plating, the plurality of feeder conductors are disconnected in the centralization region, by punching out a package base using a die. Such centralized arrangement of the plurality of feeder conductors and the disconnection at the centralization region contribute to reduce the number of site of disconnection. In addition, current supply through the planar grounding conductor makes it no more necessary to draw the feeder conductor out of the package region, and thereby prevents the package region from being divided due to the feeder conductor. It is also described that the divided feeder conductor may be made function as a stub or a shield line.

Recent advancement towards higher degree of integration and faster operation speed of semiconductor chips has raised needs for higher degrees of dimensional shrinkage of mounting terminals and interconnect patterns of semiconductor chips, wherein smaller restrictions on the pattern layout will be more preferable. However, any attempt of centralization of sites of disconnection of a plurality of feeder conductors as described in Japanese Laid-Open Patent Publication No. 2001-68588 may raise restrictions to the pattern layout, and may raise difficulty in the dimensional shrinkage. In addition, in recent semiconductor chips improved in the operation speed, any residual interconnect left unremoved therearound after the disconnection may cause large noise, and the noise may adversely affect signals input and output to and from the mounting terminals.

### SUMMARY

According to the present invention, there is provided a method of manufacturing a wiring board which includes,

an insulating base containing a predetermined mounting region at one surface thereof;

a plurality of mounting terminals arranged in the mounting region at the one surface of the insulating base;

a plane electrode formed around the plurality of mounting terminals in the mounting region on the one surface of the insulating base;

a plurality of interconnects for plating, each of which is respectively connected to the plane electrode and a plurality of the mounting terminals different from each other; and

a mask film for plating formed on the one surface of the insulating base so as to cover the insulating base, having a plurality of openings for mounting terminals respectively provided at positions corresponded to the plurality of mounting terminals while allowing the mounting terminals to expose therein, and having openings for disconnection provided on each of the plurality of the interconnects for plating at positions allowing therethrough disconnection between the plane electrode and each of the mounting terminals connected to respective the interconnect for plating while allowing the interconnects for plating to expose therein, the method including:

forming a plated film on the surfaces of the mounting terminals and the interconnects for plating exposed out from the mask film for plating on the wiring board;

disposing, on the mask film for plating, a mask for removing interconnect covering the plurality of openings for mounting terminals, and having openings at positions corresponded to at least one of the openings for disconnection on each of the plurality of interconnects for plating; and

removing, through the mask for removing interconnect, the plated film and the interconnects for plating exposed out from the mask for removing interconnect.

According to the present invention, there is provided also a wiring board including:

an insulating base containing a predetermined mounting region at one surface thereof;

a plurality of mounting terminals arranged in the mounting region at the one surface of the insulating base;

a plane electrode formed around the plurality of mounting terminals in the mounting region on the one surface of the insulating base;

a plurality of interconnects for plating, each of which is respectively connected to the plane electrode and a plurality of the mounting terminals different from each other.

According to the present invention, there is provided also a wiring board including:

an insulating base containing a predetermined mounting region at one surface thereof;

a plurality of mounting terminals arranged in the mounting region at the one surface of the insulating base;

a plane electrode formed around the plurality of mounting terminals in the mounting region on the one surface of the insulating base;

a plurality of interconnects for plating, each of which is respectively connected to the plane electrode and is formed along a plurality of paths connected to the plurality of mounting terminals different from each other; and

a mask film for plating formed on the one surface of the insulating base so as to cover the insulating base, having a plurality of openings for mounting terminals respectively provided at positions corresponded to the plurality of mounting terminals while allowing the mounting terminals to expose therein, and having openings for disconnection provided on the each of the plurality of paths at positions allowing therethrough disconnection between the plane electrode and each of the mounting terminals connected to respective the path while allowing the interconnects for plating to expose therein,

wherein the interconnects for plating are formed at positions corresponded to those excluding the openings for disconnection on each of the plurality of paths.

According to the present invention, there is provided also a semiconductor device including a wiring board which includes,

an insulating base containing a predetermined mounting region at one surface thereof;

a plurality of mounting terminals arranged in the mounting region at the one surface of the insulating base;

a plane electrode formed around the plurality of mounting terminals in the mounting region on the one surface of the insulating base;

a plurality of interconnects for plating, each of which is respectively connected to the plane electrode and is formed along a plurality of paths connected to the plurality of mounting terminals different from each other; and

a mask film for plating formed on the one surface of the insulating base so as to cover the insulating base, having a plurality of openings for mounting terminals respectively provided at positions corresponded to the plurality of mounting terminals while allowing the mounting terminals to expose therein, and having openings for disconnection provided on the each of the plurality of paths at positions allowing therethrough disconnection between the plane electrode and each of the mounting terminals connected to respective the path while allowing the interconnects for plating to expose therein; and

a semiconductor chip disposed on the wiring board, and electrically connected to at least one of the mounting terminals;

wherein the interconnects for plating are formed at positions corresponded to those excluding the openings for disconnection on each of the plurality of paths.

According to the above described configurations, a plurality of interconnects for plating, each of which having a plurality of mounting terminals connected thereto, are connected to the plane electrode formed around the mounting terminals. By virtue of this configuration, even if it is necessary to densely arrange a large number of mounting terminals, current may be fed through any of interconnects for plating from the plane electrode, while ensuring a large degree of freedom in the pattern layout. For example, in a conventional dense interconnect pattern, it has been difficult to connect the interconnects for plating to the mounting terminals arranged deep inside the mounting region. However, according to the above-described configuration, such mounting terminals may be connected to the plane electrode, by branching the interconnects for plating, or by placing other mounting terminals in between. It is, therefore, no more necessary to extend long interconnects for plating, and thereby the interconnects for plating, which will later be no more necessary, may be prevented from being unnecessarily elongated. By virtue of this configuration, the mounting terminals may be arranged according to a degree of freedom of designing almost equivalent to that in electroless plating which intrinsically needs no interconnects for plating.

After the plating, the mounting terminals may be disconnected from the plane electrode and from other mounting terminals, by disconnecting the interconnects for plating. As a consequence, noises possibly contaminating signals input and output to and from the mounting terminals may be reduced, and electrical characteristics of a power source or the signals may be improved. The one surface of the wiring board herein means the surface allowing thereon mounting of semiconductor chips, or the surface faced to the mother board in a mounted state.

Any arbitrary combinations of the above-described constituents, and any expressions of the present invention exchanged among the method, the device and so forth may be effective as embodiments of the present invention.

According to the present invention, the degree of freedom of pattern layout may be improved, and noises contaminating input and output to and from the mounting terminals may be reduced.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a flow chart showing procedures of processes in one embodiment of the present invention;

FIGS. 2A and 2B are schematic plan views showing an exemplary configuration of the top surface of a wiring board according to one embodiment of the present invention;

FIG. 3 and FIG. 4 are plan views showing an example of specific configuration of the surface of a wiring board according to one embodiment of the present invention;

FIG. 5 is a plan view showing a configuration of a mask for removing interconnect according to one embodiment of the present invention;

FIG. 6 and FIG. 7 are plan views showing an exemplary configuration of the top surface of a wiring board in one embodiment of the present invention;

FIG. 8 and FIG. 9 are plan views showing an exemplary configuration of the back surface of a wiring board in another embodiment of the present invention;

FIG. 10 is a plan view showing a configuration of a mask for removing interconnect according to another embodiment of the present invention;

FIG. 11 and FIG. 12 are plan views showing an example of specific configuration of the back surface of a wiring board in another embodiment of the present invention;

FIGS. 13A, 13B, 14A, 14B and 15 are sectional views showing procedures of processing in one embodiment of the present invention; and

FIGS. 16 to 18 are plan views showing other examples of specific configuration of the top surface of the wiring board in other embodiments of the present invention wiring board.

### DETAILED DESCRIPTION

The invention will now be described herein with reference to an illustrative embodiments. Those skilled in the art will recognize that many alternative embodiments can be accomplished using the teachings of the present invention and that the invention is not limited to the embodiment illustrated for explanatory purposes.

Paragraphs below will explain embodiments of the present invention, referring to the attached drawings. In all drawings, any similar constituents will be given with similar reference numerals, so as to avoid repetitive explanation.

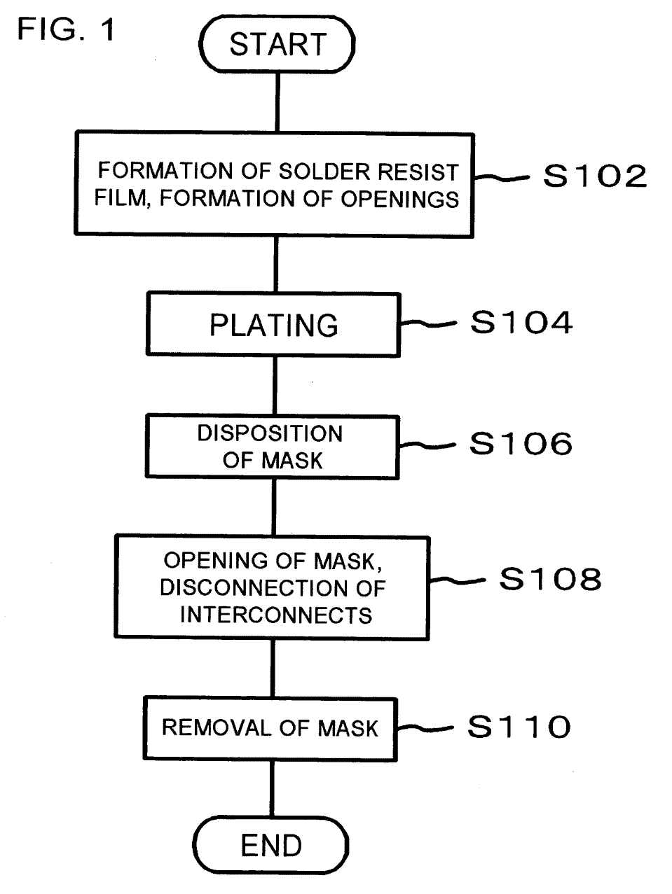

FIG. 1 is a flow chart showing procedures of manufacturing a wiring board in this embodiment.

In the embodiments below, the wiring board having a plurality of mounting terminals formed thereon will be manufactured according to the procedures described below. The explanation below will deal with processes provided to the top surface of the wiring board, wherein processes may similarly be provided also to the back surface of the wiring board. The wiring board herein may have a multilayer structure. The explanation below will deal with the case where a semiconductor chip is mounted on the top surface of the wiring board, and the wiring board is mounted on the back surface side thereof onto a mother board.

The wiring board herein may contain an insulating base containing a predetermined mounting region, and may allow the surface of the insulating base to expose to the top and back surfaces of the wiring board. The mounting region on the top surface of the insulating base may be configured as having an interconnect pattern formed thereon, wherein the interconnect pattern contains a plurality of mounting terminals, a plane electrode formed around the plurality of mounting terminals, and a plurality of interconnects for plating respectively connected to the plane electrode, and connected to a plurality of the plane electrode mounting terminals different from each other. It means that each of the interconnects for plating is connected to the plane electrode and a plurality of the plane electrode mounting terminals which are not connected to other interconnects for plating.

On the insulating base of thus-configured wiring board, a solder resist film (mask film for plating) is formed so as to cover the entire surface the insulating base, and openings are then formed in the solder resist film (S102). The openings herein may contain a plurality of openings for mounting terminals respectively provided at positions corresponded to the plurality of mounting terminals while allowing the mounting terminals to expose therein, and having openings for disconnection provided on each of the interconnects for plating at positions allowing therethrough disconnection between the plane electrode and each of the mounting terminals connected to the respective interconnect for plating while allowing the interconnects for plating to expose therein.

Next, a plated film is formed on the surfaces of the mounting terminals and interconnects for plating exposed out from the mask film for plating (S104).

Next, a mask for removing interconnect, covering the plurality of openings for mounting terminals, and having openings at positions corresponded to at least one of the openings for disconnection on each of the interconnects for plating, is disposed on the solder resist film (S106).

Thereafter, through the mask for removing interconnect, the plated film and the interconnects for plating exposed out from the mask for removing interconnect are removed, to thereby disconnect the interconnects for plating (S108).

Next, the mask for removing interconnect is removed (S110).

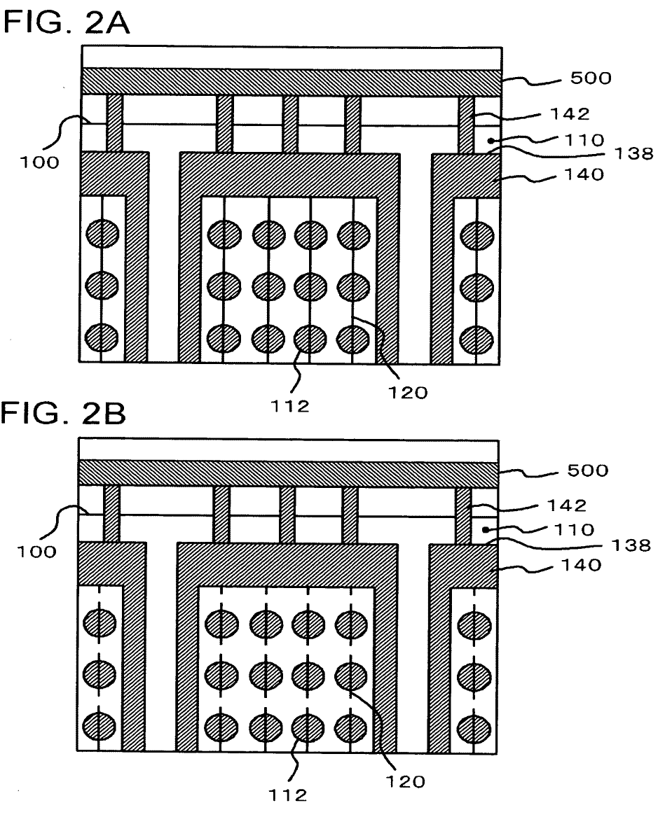

FIGS. 2A and 2B are schematic plan views showing an exemplary configuration of the top surface of the wiring board of this embodiment. FIG. 2A is a drawing showing a state before disconnection of the interconnects for plating 120.

As shown in FIG. 2A, a plurality of predetermined mounting regions 138 are provided to the top surface of the insulating base 110. In each mounting region 138, there are provided a plurality of mounting terminals 112, a plane electrode 140 formed around the plurality of mounting terminals 112, and a plurality of interconnects for plating 120 respectively connected to the plane electrode 140, and connected to the plurality of mounting terminals 112 different from each other. Each plane electrode 140 is extended to as far as the outer periphery of each mounting region 138. Each plane electrode 140 is connected via extension interconnects 142 to a feeder conductor 500 provided to the external of the wiring board 100.

When plating onto each of the mounting terminals takes place in this configuration, electric current flows from the feeder conductor 500 and the extension interconnects 142 through the plane electrode 140 to the interconnects for plating 120, and further through each of the mounting terminals 112. FIG. 2A shows an exemplary configuration having a plurality of extension interconnects 142 provided for each of the plane electrodes 140, whereas only a single extension interconnect 142 may be provided to each of the plane electrodes 140. Provision of a plurality of extension interconnects 142 may reduce the resistivity or may feed a high-power current, but the mode of provision is not limited thereto.

FIG. 2B is a drawing showing a state after disconnection of the interconnects for plating 120. In this example, a plurality of portions for disconnection are provided on each of the interconnects for plating 120, so as to disconnect each of the mounting terminals 112 respectively from the respective plane electrode 140.

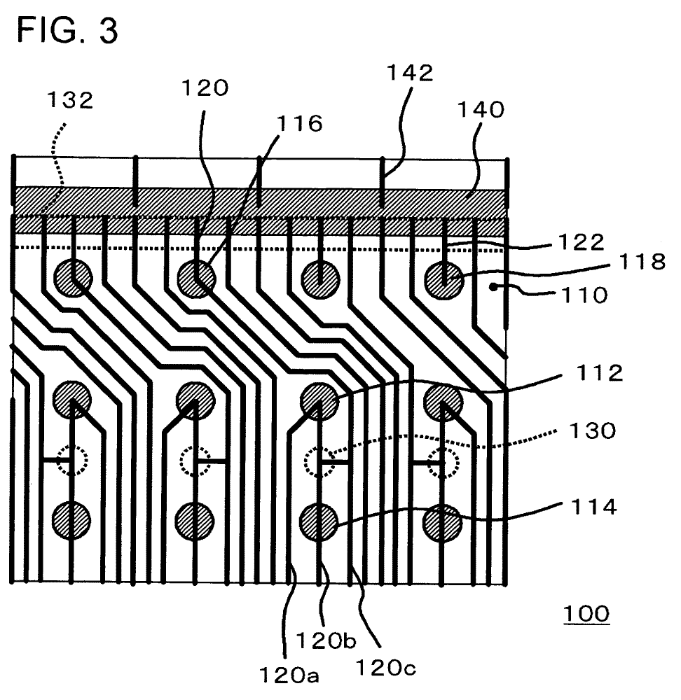

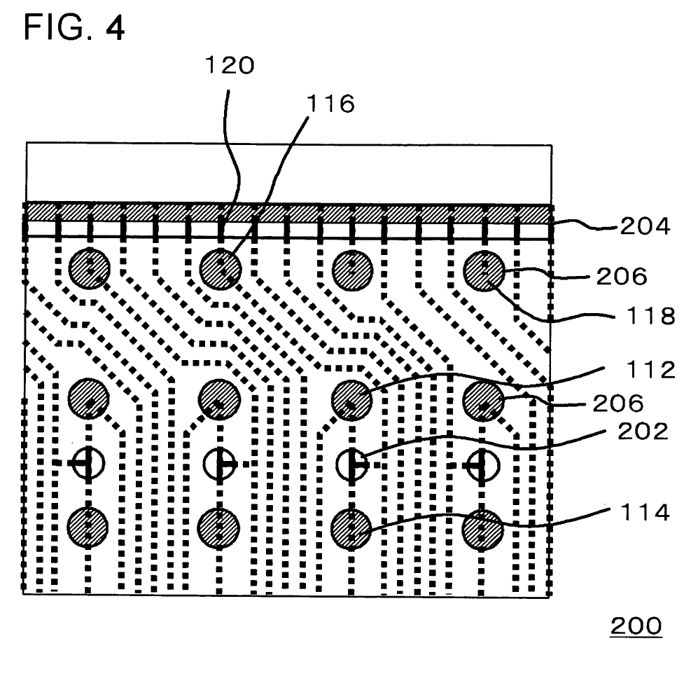

FIG. 3 and FIG. 4 are plan views showing an example of specific configuration of the wiring board 100 in this embodiment. The drawing show a portion of the mounting region 138 shown in FIG. 2A.

FIG. 3 shows a configuration of the top surface of the insulating base 110 before disconnection of the interconnects for plating. A plurality of interconnects for plating and mounting terminals hereinafter will be given with different reference numerals for the convenience of explanation.

The interconnects for plating, such as the interconnect for plating 120, an interconnect for plating 122 and so forth are electrically connected to the plane electrode 140. The interconnect for plating 120 located between the mounting terminals and the plane electrode 140 has a branching point, and is configured as being branched out therefrom to interconnects 120a, 120b, and 120c. The mounting terminal 112, the mounting terminal 114, and the mounting terminal 116 may be configured as being respectively connected to internal hole terminals or the like (not shown) through interconnects 120a, 120b, and 120c. The mounting terminal 112, the mounting terminal 114, and the mounting terminal 116 are connected to the plane electrode 140 through the interconnect for plating 120. Of these mounting terminals 112, 114, and 116, the mounting terminals 112 and 114 are respectively connected to the interconnect for plating 120 at the destinations of branching originated from the branching point of the interconnects for plating 120. The interconnect for plating 120 is drawn out from the plane electrode 140, connected to the mounting terminal 116, further drawn out from the mounting terminal 116, and connected respectively to the mounting terminal 112 and mounting terminal 114. As has been described in the above, this embodiment allows provision of a hierarchy of connection (first to n-th hierarchies), such as providing a primary interconnect drawn out from the plane electrode 140 to the neighboring mounting terminal 116, and providing a secondary interconnect to the plane electrode 140 while using the mounting terminal 116 as an intermediate. By virtue of this configuration, the mounting terminals may be connected to the plane electrode 140 making full use of a minimum space, even on the insulating base 110 having a large density of interconnect, and therefore raising difficulty in drawing the interconnects for plating respectively out from the plane electrode 140.

On the top surface of the insulating base 110, there are provided also a plurality of interconnects similar to the interconnect for plating 120. The interconnect for plating 122 herein is connected only to a single mounting terminal 118. As described in the above, this embodiment allows provision of various patterns of combinations of the interconnects for plating and the mounting terminals on the insulating base 110. These interconnect patterns may be formed typically by patterning a copper foil formed on the top surface of the insulating base 110 by etching, or by plating. The plane electrode 140 is connected through the extension interconnects 142 to the feeder conductor 500 (see FIGS. 2A and 2B).

Portions of disconnection 130 and a portion of disconnection 132 are portions where the interconnects for plating are removed by selective etching after the plating. By virtue of such configuration of the interconnect for plating 120, in the process of plating onto the mounting terminals, current may be fed through a single interconnect for plating 120 to a number of mounting terminals (112, 114 and 116). In addition, by disconnecting these mounting terminals after the plating, antenna patterns (unterminated interconnects) possibly causative of adverse electromagnetic influences, stub interconnect, and interconnects for plating remained floated without being connected to any terminals, may be disconnected at arbitrary sites and into arbitrary length. Moreover, the interconnects for plating between each of the mounting terminals, and between the plane electrode and the mounting terminals are disconnected after the plating, so that density of plated conductors (area, number of lines) as a whole may also be minimized.

FIG. 4 shows a configuration of the surface of the solder resist film 200 before disconnection of the interconnects for plating.

The solder resist film 200 is formed on the insulating base 110, so as to cover the insulating base 110. The solder resist film 200 has a plurality of openings for disconnection 202 at positions corresponded to each of the portions of disconnection 130 shown in FIG. 3, an opening for disconnection 204 provided at a position corresponded to the portion of disconnection 132, and a plurality of openings for mounting terminals 206 provided at positions corresponded to each of the mounting terminals. At the bottom of the openings for mounting terminals 206, the mounting terminals including the mounting terminal 112, mounting terminal 114, mounting terminal 116, and mounting terminal 118 are exposed. At the bottom of the openings for disconnection 202, the interconnects for plating including the interconnects for plating 120 are exposed. At the bottom of the opening for disconnection 204, the interconnects for plating including the interconnects for plating 120 and the interconnects for plating 122, and a portion of the plane electrode 140 are exposed. It is to be noted that the interconnects for plating, including the interconnects for plating 120 and the interconnects for plating 122, are indicated by dashed lines for simplicity of understanding, wherein these interconnects are actually configured as being covered with the solder resist film 200.

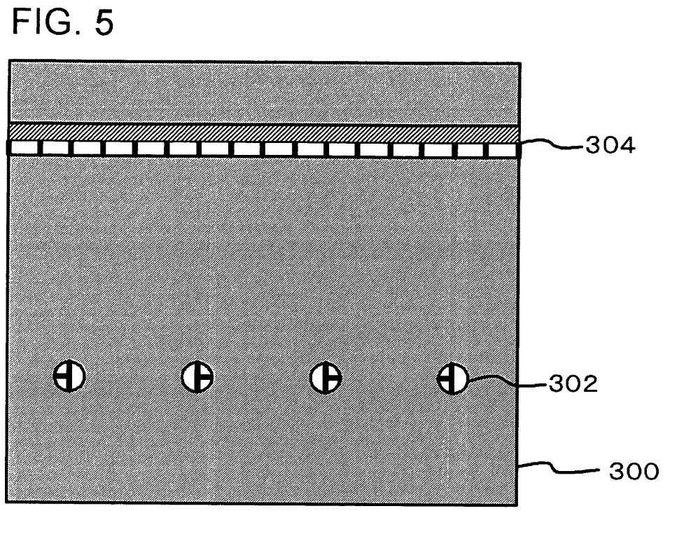

FIG. 5 is a plan view showing a configuration of the mask for removing interconnect, used for removing the portions of disconnection 130 and the portion of disconnection 132 of the interconnects for plating formed on the top surface of the insulating base 110.

The mask for removing interconnect 300 is provided so as to cover the plurality of openings for mounting terminals 206, and has openings for disconnection 302 and an opening for disconnection 304 at positions corresponded to at least one of the openings for disconnection, provided on each of the interconnects for plating.

In this embodiment, a plated film is formed on the insulating base 110 using the solder resist film 200 shown in FIG. 4, the mask for removing interconnect 300 shown in FIG. 5 is then disposed on the solder resist film 200, and using these components as a mask, unnecessary portions of the interconnects for plating, such as the portion of the interconnects for plating 120 on the insulating base 110, are removed. By these processes, the portions of disconnection 130 and the portion of disconnection 132 shown in FIG. 3 are disconnected.

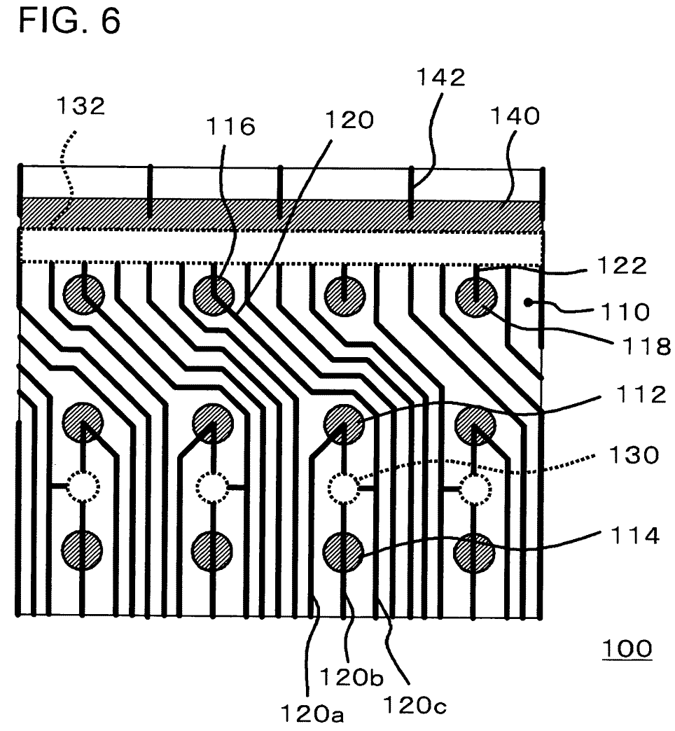

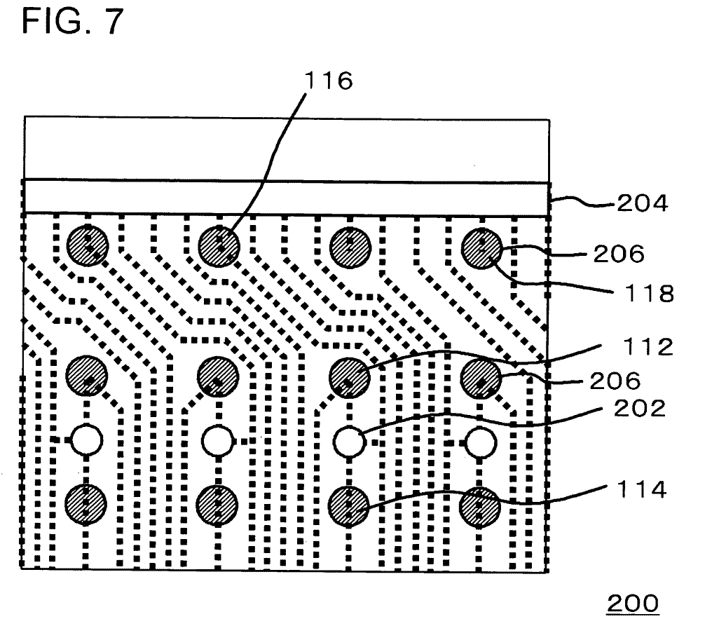

FIG. 6 and FIG. 7 are plan views showing configurations obtained after the interconnects for plating on the top surface of the insulating base 110 shown in FIG. 3 and FIG. 4 were removed using the mask for removing interconnect 300.

FIG. 6 shows a configuration of the top surface of the insulating base 110, after disconnection of the interconnects for plating. FIG. 7 shows a configuration of the surface of the solder resist film 200, after disconnection of the interconnects for plating. It is to be noted that the interconnects for plating, including the interconnects for plating 120 and the interconnects for plating 122, are indicated by dashed lines for simplicity of understanding similarly to as in FIG. 4, wherein these interconnects are actually configured as being covered with the solder resist film 200. As shown in the drawings, the interconnects for plating and the plane electrode 140 are removed selectively in the portions thereof corresponded to the portions of disconnection 130 and the portion of disconnection 132. In this example, the mounting terminal 112, the mounting terminal 114, and the mounting terminal 116 may be configured as being connected respectively through the interconnects 120a, 120b and 120c to the internal hole terminals (not shown), even after being disconnected by the portions of disconnection 130. By virtue of this configuration, the mounting terminals may be fed with electric current through the interconnects for plating 120 in the process of plating from the plane electrode 140, and may be allowed to transmit signals to and from the internal hole terminals even after the plating.

Next, another example of the interconnect pattern will be explained.

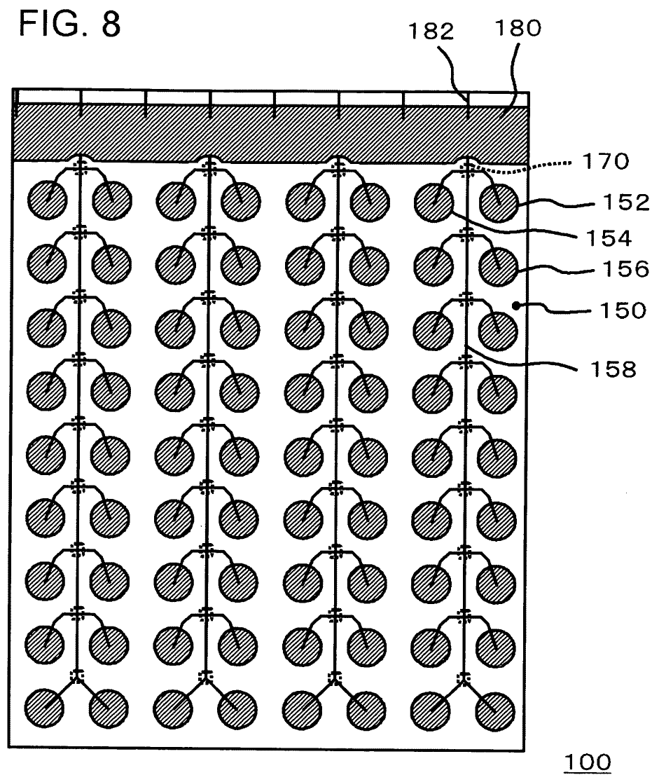

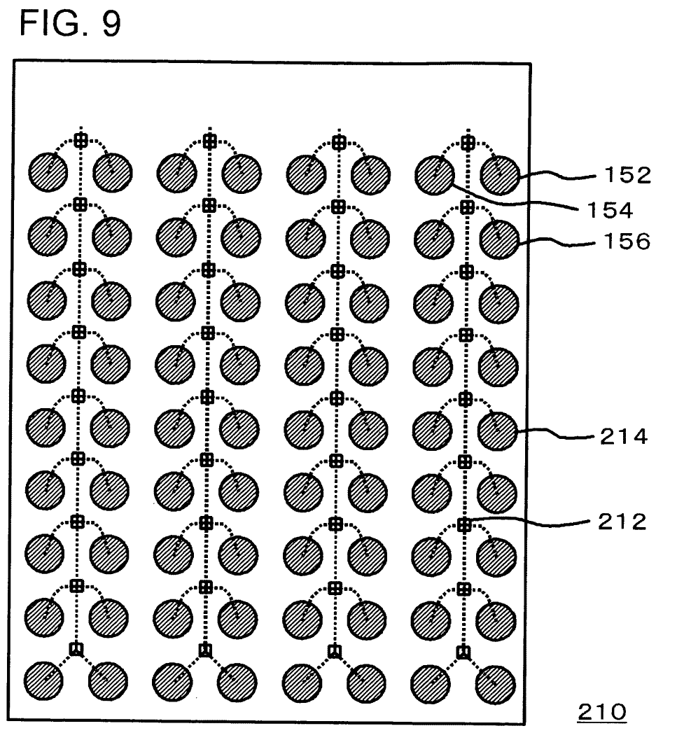

FIG. 8 and FIG. 9 are plan views showing an example of specific configuration of the back surface of the wiring board 100 of this embodiment. Although not shown in the drawings, the mounting regions corresponded to the mounting regions 138 on the top surface side are provided also on the back surface of the wiring board 100, as shown in FIG. 2A. A portion of one of the mounting regions is shown herein.

FIG. 8 shows a configuration of the back surface of the insulating base 150, before disconnection of the interconnects for plating.

To each mounting region, there are provided a plurality of mounting terminals including mounting terminal 152, mounting terminal 154 and mounting terminal 156, a plane electrode 180 formed around the plurality of mounting terminals, and a plurality of interconnects for plating 158 respectively connected to the plane electrode 180, and connected to the plurality of mounting terminals different from each other. The plane electrode 180 is extended to as far as the outer periphery of each mounting region. The plane electrode 180 is connected through extension interconnects 182 to a feeder conductor (not shown) provided to the external of the wiring board 100.

When plating onto each of the mounting terminals takes place in this configuration, electric current flows from the feeder conductor and the extension interconnects 182 through the plane electrode 180 to the interconnects for plating 158, and further through each of the mounting terminals. FIG. 8 shows an exemplary configuration having a plurality of extension interconnects 182 provided for each of the plane electrode 180s, whereas only a single extension interconnect 182 may be provided to each of the plane electrodes 180. Provision of a plurality of extension interconnects 182 may reduce the resistivity or may allow feeding of a high-power current, but the mode of provision is not limited thereto.

Each of the interconnects for plating 158 has branching points, and is configured as being branched out therefrom. In this example, each interconnect for plating 158 has a plurality of branching points provided thereto. The mounting terminal 152 and the mounting terminal 154 are connected to the interconnect for plating 158, at the destinations of branching originated from the branching point closest to the plane electrode 180. The mounting terminal 156 is connected to the interconnects for plating 158, at the destination of branching originated from the branching point second closest to the plane electrode 180. On the back surface of the insulating base 150, there are provided also a plurality of interconnects similar to the interconnect for plating 158. While only similar patterns are shown herein, also the insulating base 150 may be provided with various patterns of combination of the interconnects for plating and mounting terminals. These interconnect patterns may be formed typically by patterning a copper foil formed on the back surface of the insulating base 150 by etching, or by plating.

Portions of disconnection 170 are portions where the interconnects for plating are removed by selective etching after the plating. In this example, the portions of disconnection 170 are formed on the branching points on the interconnects for plating 158. Accordingly, a plurality of mounting terminals may be disconnected from each other, and from the plane electrode at a single portion of disconnection. By virtue of this configuration of the interconnects for plating 158, in the process of plating onto the mounting terminals, current may be fed through a single interconnect for plating 158 to a number of mounting terminals (152, 154 and 156), whereas noises contaminating signals input and output to and from the mounting terminals may be reduced, and electrical characteristics of a power source or the signals may be improved, by disconnecting the mounting terminals from each other after the plating.

FIG. 9 shows a configuration of the surface of the solder resist film 210 before disconnection of the interconnects for plating.

The solder resist film 210 is formed on the insulating base 150, so as to cover the insulating base 150. The solder resist film 210 has a plurality of openings for disconnection 212 at positions corresponded to each of the portions of disconnection 170 shown in FIG. 8, and a plurality of openings for mounting terminals 214 provided at positions corresponded to each of the mounting terminals. At the bottom of the openings for mounting terminals 214, the mounting terminals including the mounting terminal 152, mounting terminal 154, and mounting terminal 156 are exposed. At the bottom of the openings for disconnection 212, the interconnects for plating including the interconnect for plating 158 are exposed. It is to be noted that the interconnects for plating, including the interconnects for plating 158, are indicated by dashed lines for simplicity of understanding, wherein these interconnects are actually configured as being covered with the solder resist film 210.

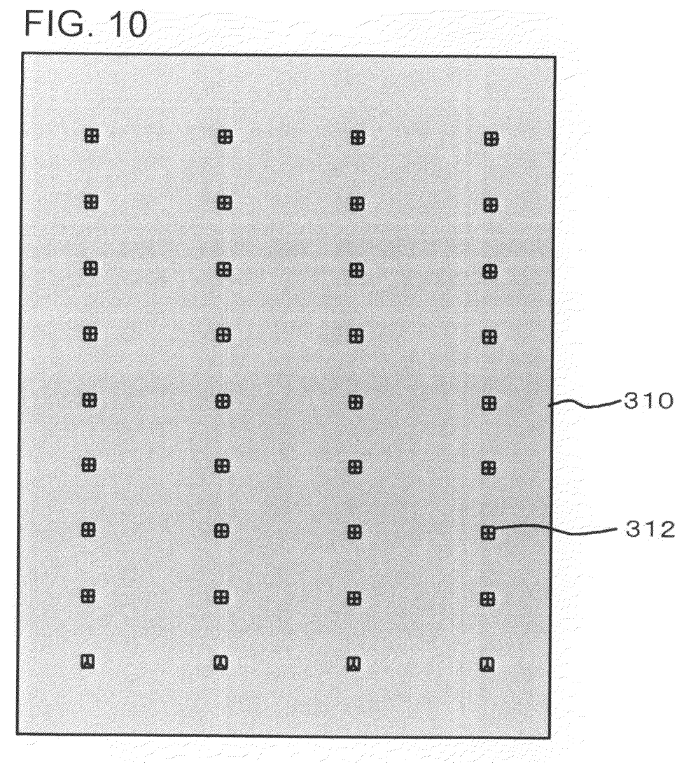

FIG. 10 is a plan view showing a configuration of the mask for removing interconnect, used for removing the portions of disconnection 170 of the interconnects for plating formed on the insulating base 150.

The mask for removing interconnect 310 is provided so as to cover the plurality of openings for mounting terminals 214, and has openings for disconnection 312 at positions corresponded to at least one of the openings for disconnection 212, provided on each the interconnects for plating.

In this embodiment, a plated film is formed on the insulating base 150 using the solder resist film 210 shown in FIG. 9, the mask for removing interconnect 310 shown in FIG. 10 is then disposed on the solder resist film 210, and using these components as a mask, unnecessary portions of the interconnects for plating, such as the portion of the interconnects for plating 158 on the insulating base 150, are removed. By these processes, the portions of disconnection 170 shown in FIG. 8 are disconnected.

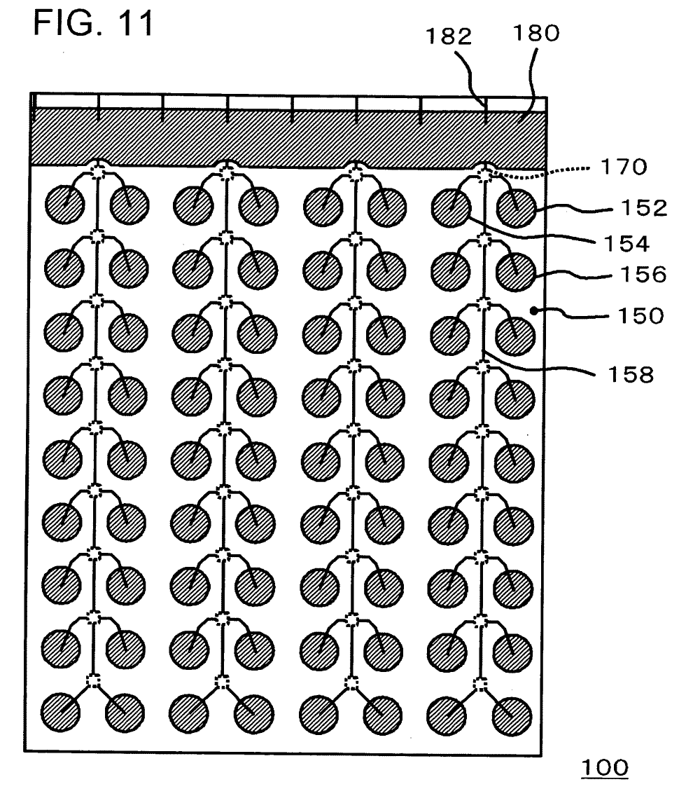

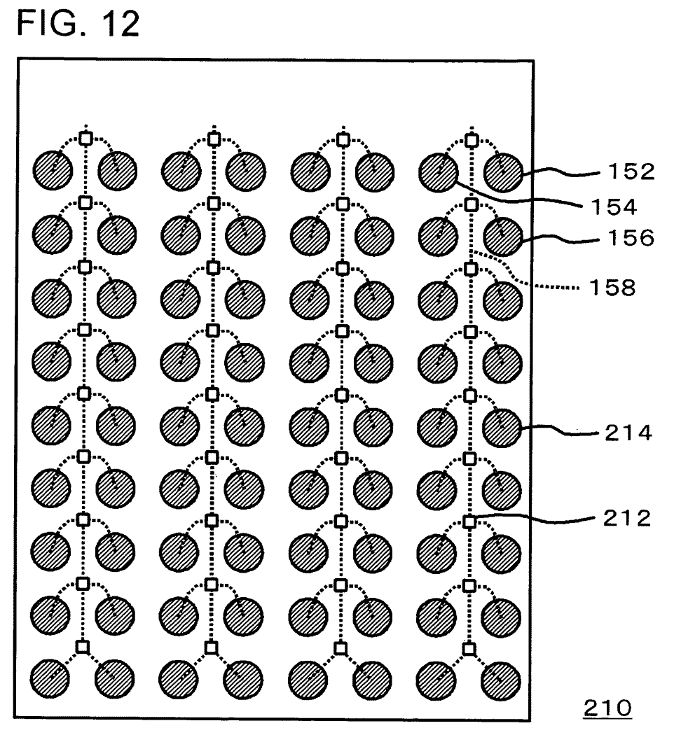

FIG. 11 and FIG. 12 are plan views showing configurations obtained after the interconnects for plating on the back surface of the insulating base 150 shown in FIG. 8 and FIG. 9 were removed using the mask for removing interconnect 310.

FIG. 11 shows a configuration of the back surface of the insulating base 150, after disconnection of the interconnects for plating 158. FIG. 12 shows a configuration of the back surface of the solder resist film 220, after disconnection of the interconnects for plating 158. It is to be noted that the interconnects for plating 158 are indicated by dashed lines for simplicity of understanding similarly to as in FIG. 9, wherein these interconnects are actually configured as being covered with the solder resist film 210. As shown in the drawings, the interconnects for plating 158 are removed selectively in the portions thereof corresponded to the portions of disconnection 170.

Next, the aforementioned processes will be explained referring to process-wise sectional views.

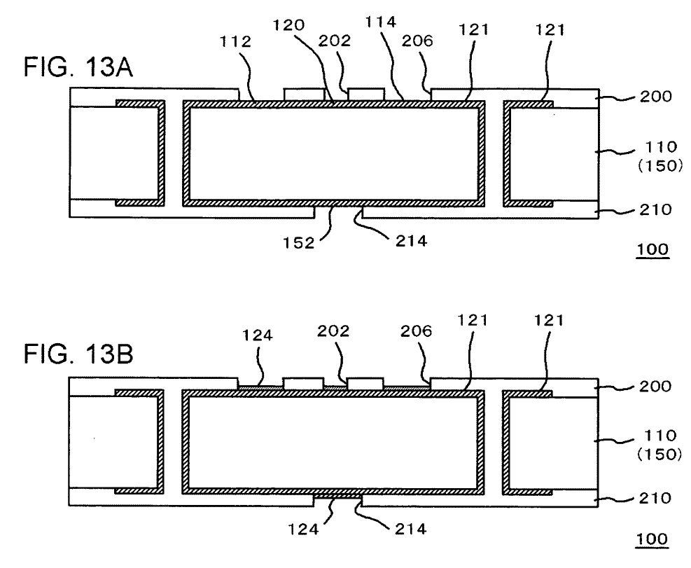

FIGS. 13A, 13B, 14A, 14B and 15 are process-wise sectional views showing procedures of electrolytic plating onto the mounting terminals on the surfaces of the insulating base 110 (150) using the interconnects for plating, and of selective etching for disconnection of the interconnects for plating after the electrolytic plating.

While the drawings herein show only a single layer of the insulating base 110 for simplicity, the wiring board 100 may be configured as having a number of insulating bases. The explanation below will be made assuming that the processes given on the top surface of the insulating base 110 explained referring to FIG. 3 to FIG. 7 are respectively proceeded on the top surface side of the insulating base 110, and the processes given on the back surface of the insulating base 150 explained referring to FIG. 8 to FIG. 12 are respectively proceeded on the back surface of the insulating base 110. The explanation below will be made, appropriately referring to any other above-described drawings including FIG. 1.

FIG. 13A is a drawing showing a state corresponded to step S102 in FIG. 1. On the top surface of the insulating base 110, there are formed an interconnect pattern 121 containing the interconnects for plating 120, the mounting terminals 112, mounting terminals 114 and so forth. On the insulating base 110, the solder resist film 200 is formed. The solder resist film 200 has the openings for mounting terminals 206 formed at positions corresponded to the mounting terminals 112 and the mounting terminals 114. The solder resist film 200 also has the openings for disconnection 202 formed at positions corresponded to the portions of disconnection of the interconnects for plating 120. It is to be noted that, also on the back surface of the insulating base 110 (insulating base 150), there are formed the interconnect patterns including the mounting terminals 152 and the interconnects for plating (not shown), and further thereon, there are formed the solder resist film 210. The solder resist film 210 has the openings for disconnection (not shown) and the openings for mounting terminals 214 formed therein.

In this state, the mounting terminals are subjected to plating. In this process, electrolytic plating is proceeded by allowing electric current to flow through the feeder conductor 500, the extension interconnects 142, the plane electrodes 140, the interconnects for plating 120 and the interconnects for plating 122, to each of the mounting terminals. By these processes, a plated film 124 is formed on the surfaces of the interconnects for plating 120 and the mounting terminals exposed at the bottom of the openings for disconnection 202 and the openings for mounting terminals 206 formed in the solder resist film 200 (FIG. 13B). The plated film 124 may be configured using Ni, Au and so forth. The electrolytic plating may similarly be provided also onto the mounting terminals 152 on the back surface of the insulating base 110, by feeding electric current through the feeder conductor, the extension interconnects 182, the plane electrodes 180 and the interconnects for plating 158 to each of the mounting terminals. The drawing herein shows a state of formation of the plated film 124 also on the mounting terminals 152.

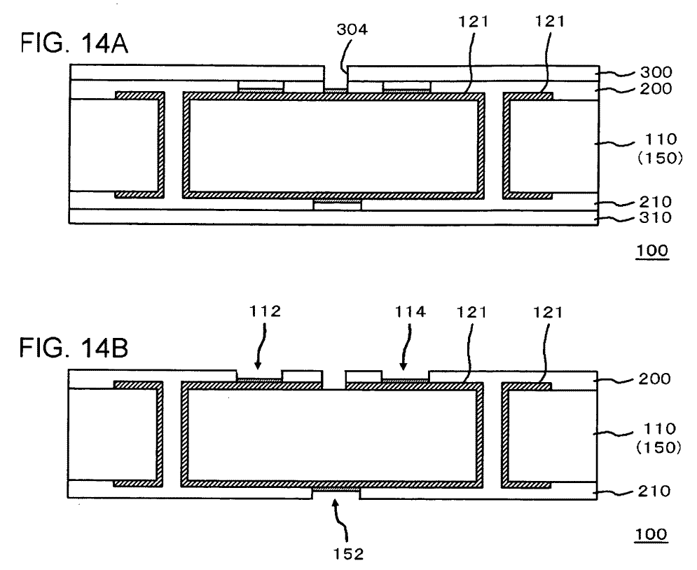

Thereafter, the mask for removing interconnect 300 is disposed on the solder resist film 200. On the solder resist film 210 on the back surface side of the insulating base 110, the mask for removing interconnect 310 is disposed (FIG. 14A).

In this state, portions of the plated film 124 and the interconnects for plating 120 exposed out from the mask for removing interconnect 300 and the mask for removing interconnect 310 are removed by using an etching solution. As a consequence, the interconnects for plating are disconnected. The mask for removing interconnect 300 and the mask for removing interconnect 310 are then removed. By these processes, the configuration shown in FIG. 14B may be obtained.

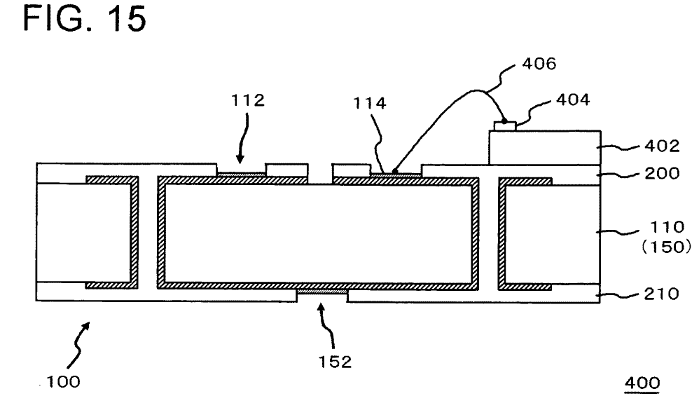

A semiconductor chip 402 is then mounted on the wiring board 100, and pads 404 and the mounting terminals 114 and so forth on the wiring board 100 are connected through bonding wires 406. A semiconductor device 400 may be thus formed (FIG. 15).

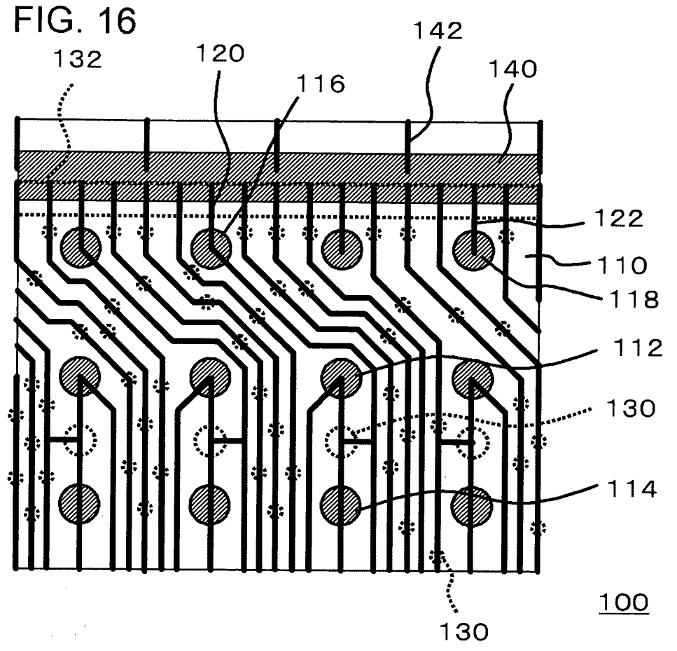

FIG. 16 shows another example of a configuration of the top surface of the insulating base 110 before disconnection of the interconnects for plating.

This example is similar to that shown in FIG. 3, except that a plurality of portions of disconnection 130 are provided between the plane electrode 140 and each of the mounting terminals. Disconnection of the interconnects for plating including the interconnects for plating 120, which will later be no more necessary after the plating, at a number of portions of disconnection may enhance the effect of reducing noises possibly contaminating signals input and output to and from the mounting terminals, and of improving electrical characteristics of the power source and the signals.

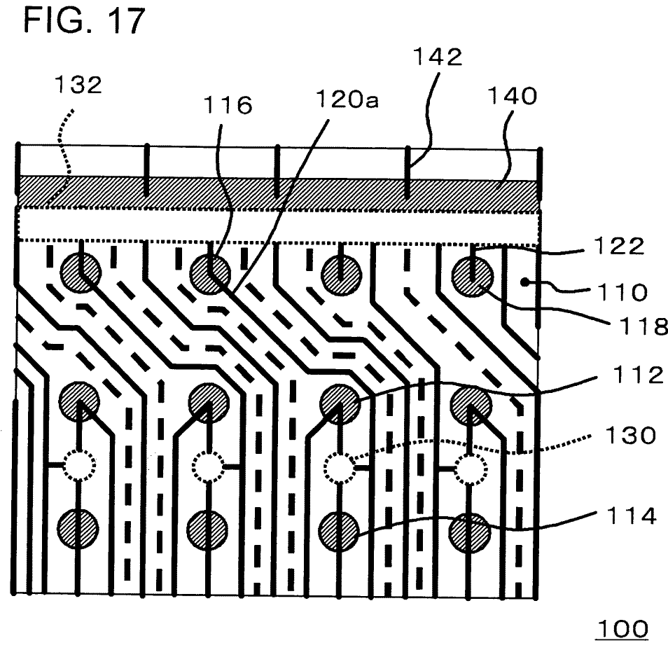

FIG. 17 shows another example of a configuration of the top surface of the insulating base 110 after disconnection of the interconnects for plating.

This example is similar to that shown in FIG. 6, except that the interconnects for plating between each plane electrode 140 and each of the mounting terminals, which will later be no more necessary after the plating, are removed over the entire portions thereof. It is to be noted that thus culled interconnects are indicated by dashed lines for simplicity of understanding in the drawing, wherein these interconnects are actually removed.

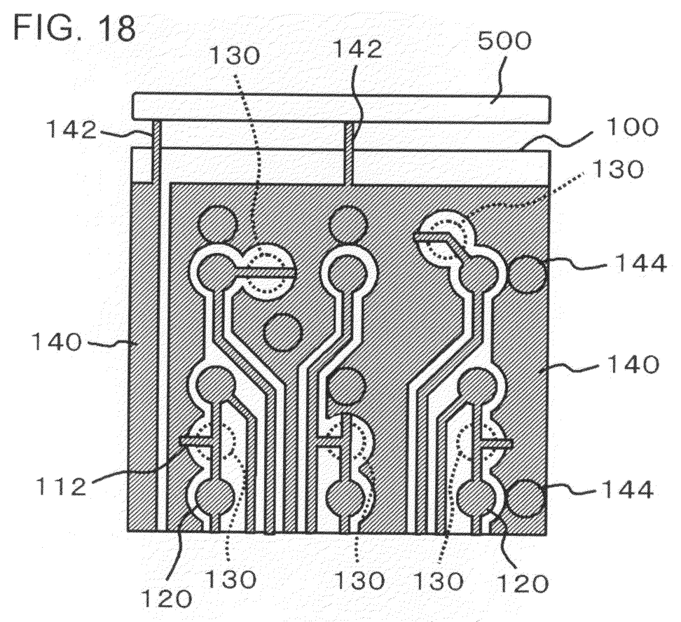

FIG. 18 is a plan view showing still another example of a configuration of the top surface of the wiring board 100. In this example, the plane electrode 140 is formed while being entangled with the individual networks composed of the interconnects for plating 120 and the mounting terminals 112. In the drawing, reference numeral 144 represents a via land. The configuration may further improve the degree of freedom of designing.

As has been described in the above, according to the configuration of this embodiment, the external feeder conductor and the plane electrodes are electrically connected, and a plurality of interconnects for plating are connected to the plane electrode. By virtue of this configuration, the number of extension interconnects connected to the feeder conductor may be reduced, and thereby the degree of freedom of layout of the interconnects for plating may be enhanced.

In addition, the interconnects for plating are removed, and thereby disconnected, at desired positions of the interconnects for plating using the solder resist film and the mask for removing interconnect. In other words, according to the embodiments of the present invention, the portions of disconnection of the interconnects for plating, which will later be no more necessary after the plating, may arbitrarily be determined on a single interconnect for plating, without limiting the quantity and location thereof. By virtue of this configuration, the unnecessary interconnects may be disconnected and removed, and thereby any noises possibly contaminating signals input and output to and from the mounting terminals may be reduced, and electrical characteristics of the power source and the signals may be improved. By removing the unnecessary interconnects, also short-circuiting between the interconnects for plating may be avoidable.

The embodiments of the present invention have been described in the above referring to the attached drawings, only as mere examples of the present invention, wherein any other configurations other than those described in the above may be adoptable.

It is apparent that the present invention is not limited to the above embodiment, that may be modified and changed without departing from the scope and spirit of the invention.

What is claimed is:

1. A method of manufacturing a wiring board which includes,
an insulating base containing a predetermined mounting region at one surface thereof;
a plurality of mounting terminals arranged in said mounting region at said one surface of said insulating base;
a plane electrode formed around said plurality of mounting terminals in said mounting region on said one surface of said insulating base;
a plurality of interconnects for plating, each of which is respectively connected to said plane electrode and a plurality of said mounting terminals different from each other; and
a mask film for plating formed on said one surface of said insulating base so as to cover said insulating base, having a plurality of openings for mounting terminals respectively provided at positions corresponded to said plurality of mounting terminals while allowing said mounting terminals to expose therein, and having openings for disconnection provided on each of said plurality of said interconnects for plating at positions allowing therethrough disconnection between said plane electrode and each of said mounting terminals connected to respective said interconnect for plating while allowing said interconnects for plating to expose therein, said method comprising:
forming a plated film on the surfaces of said mounting terminals and said interconnects for plating exposed out from said mask film for plating on said wiring board;
disposing, on said mask film for plating, a mask for removing interconnect covering said plurality of openings for mounting terminals, and having openings at positions corresponded to at least one of said openings for disconnection on each of said plurality of interconnects for plating; and
removing, through said mask for removing interconnect, said plated film and said interconnects for plating exposed out from said mask for removing interconnect.

2. The method of manufacturing a wiring board as claimed in claim 1,
wherein, in said disposing said mask for removing interconnect, said mask for removing interconnect having at least a plurality of said openings on said each of said plurality of interconnects for plating is disposed, and
in said removing said interconnects for plating, each of said plurality of interconnects for plating is disconnected at a plurality of positions.

3. A wiring board comprising:
an insulating base containing a predetermined mounting region at one surface thereof;
a plurality of mounting terminals arranged in said mounting region at said one surface of said insulating base;
a plane electrode formed around said plurality of mounting terminals in said mounting region on said one surface of said insulating base;
a plurality of interconnects for plating, each of which is respectively connected to said plane electrode and a plurality of said mounting terminals different from each other.

4. The wiring board as claimed in claim 3, further comprising:
a mask film for plating formed on said one surface of said insulating base so as to cover said insulating base, having a plurality of openings for mounting terminals respectively provided at positions corresponded to said plurality of mounting terminals while allowing said mounting terminals to expose therein, and having openings for disconnection provided on each of said plurality of interconnects for plating at positions allowing therethrough disconnection between said plane electrode and each of said mounting terminals connected to respective said interconnect for plating while allowing said interconnects for plating to expose therein.

5. The wiring board as claimed in claim 4,
wherein said mask film for plating has a plurality of said openings for disconnection on each of said plurality of interconnects for plating.

6. The wiring board as claimed in claim 3,
wherein each of said plurality of interconnects for plating has a branching point, and each interconnect branched out from said branching point is connected at the destination of branching to at least one of said mounting terminals.

7. The wiring board as claimed in claim 4,
wherein each of said plurality of interconnects for plating has a branching point, and each interconnect branched out from said branching point is connected at the destination of branching to at least one of said mounting terminals, and
said mask film for plating has at least one of said openings for disconnection on said branching point, on each of said interconnects for plating.

8. The wiring board as claimed in claim 3,
wherein each of said interconnects for plating is connected to one of said mounting terminals, and further therefrom to another one of said mounting terminals.

9. A wiring board comprising:
an insulating base containing a predetermined mounting region at one surface thereof;
a plurality of mounting terminals arranged in said mounting region at said one surface of said insulating base;
a plane electrode formed around said plurality of mounting terminals in said mounting region on said one surface of said insulating base;
a plurality of interconnects for plating, each of which is respectively connected to said plane electrode and is formed along a plurality of paths connected to said plurality of mounting terminals different from each other; and
a mask film for plating formed on said one surface of said insulating base so as to cover said insulating base, having a plurality of openings for mounting terminals respectively provided at positions corresponded to said plurality of mounting terminals while allowing said mounting terminals to expose therein, and having openings for disconnection provided on said each of said plurality of paths at positions allowing therethrough disconnection between said plane electrode and each of said mounting terminals connected to respective said path while allowing said interconnects for plating to expose therein,
wherein said interconnects for plating are formed at positions corresponded to those excluding said openings for disconnection on each of said plurality of paths.

10. The wiring board as claimed in claim 9,
wherein said mask film for plating has a plurality of said openings for disconnection on each of said plurality of paths.

11. The wiring board as claimed in claim 9,
wherein each of said paths has a branching point, and each path branched out from said branching point is connected at the destination of branching to at least one of said mounting terminals.

12. The wiring board as claimed in claim 11,
wherein said mask film for plating has at least one of said openings for disconnection on said branching point, on each of said plurality of paths.

13. The wiring board as claimed in claim 9,
wherein each of said paths is connected to one of said mounting terminals, and further therefrom to another one of said mounting terminals.

14. The wiring board as claimed in claim 9,
wherein said mask film for plating is a solder resist film.

15. A semiconductor device comprising:
a wiring board which includes,
an insulating base containing a predetermined mounting region at one surface thereof;
a plurality of mounting terminals arranged in said mounting region at said one surface of said insulating base;
a plane electrode formed around said plurality of mounting terminals in said mounting region on said one surface of said insulating base;
a plurality of interconnects for plating, each of which is respectively connected to said plane electrode and is formed along a plurality of paths connected to said plurality of mounting terminals different from each other; and
a mask film for plating formed on said one surface of said insulating base so as to cover said insulating base, having a plurality of openings for mounting terminals respectively provided at positions corresponded to said plurality of mounting terminals while allowing said mounting terminals to expose therein, and having openings for disconnection provided on said each of said plurality of paths at positions allowing therethrough disconnection between said plane electrode and each of said mounting terminals connected to respective said path while allowing said interconnects for plating to expose therein; and
a semiconductor chip disposed on said wiring board, and electrically connected to at least one of said mounting terminals;
wherein said interconnects for plating are formed at positions corresponded to those excluding said openings for disconnection on each of said plurality of paths.
